(19) United States
(12) Patent Application Publication
(10) Pub. No.: US 2021/0376013 A1
(43) Pub. Date: Dec. 2, 2021

(54) DISPLAY PANEL, DISPLAY DEVICE AND METHOD FOR MANUFACTURING DISPLAY PANEL

(71) Applicant: BOE Technology Group Co., Ltd., Beijing (CN)

(72) Inventor: Yanliu Sun, Beijing (CN)

(21) Appl. No.: 16/333,674

(22) PCT Filed: Sep. 21, 2018
(86) PCT No.: PCT/CN2018/107077

§ 371 Date: Mar. 15, 2019

(30) Foreign Application Priority Data
Oct. 31, 2017 (CN) 201711051292.1

(51) Int. Cl. H01L 27/32; H01L 51/52; H01L 51/56

(52) U.S. Cl. CPC H01L 27/3227; H01L 51/5284; H01L 27/3276; H01L 2227/323; H01L 51/56; H01L 27/3218; H01L 51/5237

(57) ABSTRACT

A display panel, a display device and a method for manufacturing the display panel are provided. The display panel comprises a substrate (101), a light-emitting device (102) and a plurality of optical sensing modules (104), the light-emitting device (102) and the plurality of optical sensing modules (104) are located on one side of the substrate (101). The plurality of optical sensing modules (104) are located on a side, away from the substrate (101), of the light-emitting device (102), wherein an orthographic projection of each optical sensing module (104) on the light-emitting device (102) is located within a non-light-emitting region (P) of the light-emitting device (102). The reliability of fingerprint recognition on the display panel is improved.

This application is a 371 of PCT Patent Application Ser. No. PCT/CN2018/107077, filed on Sep. 21, 2018, which claims priority to Chinese Patent Application No. 201711051292.1, filed on Oct. 31, 2017 and entitled “DISPLAY PANEL AND MANUFACTURING METHOD THEREOF, AND DISPLAY DEVICE”, the entire contents of which are incorporated herein by reference.

### TECHNICAL FIELD

The present disclosure relates to a display panel, a display device and a method for manufacturing a display panel.

### BACKGROUND

With the rapid development of display technology, full-screen fingerprint recognition in a display region of a self-luminous display panel has already been realized at present. The self-luminous display panel may be an Organic Light-Emitting Diode (OLED) display panel, etc., and may contain Thin Film Transistors (TFTs) and light-emitting devices.

### SUMMARY

In one aspect, a display panel is provided. The display panel comprises a substrate, a light-emitting device and a plurality of optical sensing modules, the light-emitting device and the plurality of optical sensing modules are located on one side of the substrate, the plurality of optical sensing modules are located on a side, away from the substrate, of the light-emitting device; wherein an orthographic projection of each optical sensing module on the light-emitting device is located within a non-light-emitting region of the light-emitting device.

Optionally, each optical sensing module comprises an optical sensor and a light-shielding pattern; an opening is located in the light-shielding pattern; the opening is located on a side on which the light receiving face of the optical sensor is located; and an orthographic projection of the opening on the substrate and an orthographic projection of the light receiving face of the optical sensor on the substrate overlap each other.

Optionally, a caliber of the opening is in positive correlation with a thickness of the light-shielding pattern.

Optionally, the opening is a circular opening; and the ratio of the thickness of the light-shielding pattern to the caliber of the opening is greater than 8.

Optionally, the display panel further comprises a conductive wire and a processing component; the conductive wire is configured to connect the optical sensor and the processing component; the processing component is configured to recognize a fingerprint pattern in accordance with electrical signals transmitted by the optical sensor, and the electrical signals are generated based on optical signals received by the optical sensor.

Optionally, the conductive wire is located between the light-emitting device and the plurality of optical sensing modules, and an orthographic projection of the conductive wire on the light-emitting device is located within the non-light-emitting region.

Optionally, the optical sensor comprises a first electrode, a first carrier injection layer, a current generation layer, a second carrier injection layer and a second electrode which are sequentially located in a direction away from the light-emitting device; and wherein the first electrode is a non-transparent electrode, and the second electrode is a transparent electrode.

Optionally, the display panel further comprises a thin film transistor electrically connected to the optical sensor, wherein a light-shielding material is located on a side, close to the substrate, of a channel region of the thin film transistor; and the thin film transistor is configured to control exposure time of the optical sensor.

Optionally, the light-emitting device comprises a plurality of pixel units in periodic arrangement; and the plurality of optical sensing modules and the plurality of pixel units are in one-to-one correspondence.

Optionally, the light-shielding pattern is made from black matrix material.

Optionally, a light-emitting region of the light-emitting device comprises a first electrode, a light-emitting layer and a second electrode which are sequentially located on the substrate in a direction away from the substrate; and the first electrode is one of an anode and a cathode, and the second electrode is the other.

Optionally, the display panel further comprises an insulating film encapsulation layer located on a side, away from the substrate, of the light-emitting device.

Optionally, the optical sensing module is located on a side, away from the substrate, of the insulating film encapsulation layer.

Optionally, the optical sensor is located between the light-emitting device and the insulating film encapsulation layer, and the light-shielding pattern is located on a side, away from the substrate, of the insulating film encapsulation layer.

In another aspect, a display device comprising a display panel is provided. The display panel comprises a substrate, a light-emitting device and a plurality of optical sensing modules, the light-emitting device and the plurality of optical sensing modules are located on one side of the substrate, the plurality of optical sensing modules are located on a side, away from the substrate, of the light-emitting device; wherein an orthographic projection of each optical sensing module on the light-emitting device is located within a non-light-emitting region of the light-emitting device.

In yet another aspect, a method for manufacturing a display panel is provided. The method comprises: providing a substrate; forming a light-emitting device on the substrate; forming a plurality of optical sensing modules on a non-light-emitting region on a side, away from the substrate, of the light-emitting device.

Optionally, said forming a plurality of optical sensing modules on a non-light-emitting region on a side, away from the substrate, of the light-emitting device comprises: forming a plurality of optical sensors on the non-light-emitting region on the side, away from the substrate, of the light-emitting device; forming a plurality of light-shielding patterns in one-to-one correspondence with the plurality of optical sensors on the substrate on which the plurality of optical sensors are formed, openings are formed in the light-shielding patterns, the opening is located on a side on which the light receiving face of the optical sensor is located, and an orthographic projection of the opening on the substrate and an orthographic projection of the light receiving face of the optical sensor on the substrate overlap each other.

Optionally, after said forming the light-emitting device on the substrate, the method further comprises: forming a conductive wire on the substrate on which the light-emitting device is formed; said forming a plurality of optical sensors on a non-light-emitting region on a side, away from the substrate, of the light-emitting device comprises: forming the optical sensors on the substrate on which the conductive wire is formed, and the conductive wire is connected with the optical sensors.

Optionally, said forming a conductive layer on the substrate on which the light-emitting device is formed comprises: forming the conductive wire on the non-light-emitting region on the side, away from the substrate, of the light-emitting device by means of sputtering under the condition that a temperature is lower than a target temperature, the target temperature being the highest tolerable temperature of the light-emitting device.

Optionally, said forming a plurality of optical sensors on a non-light-emitting region on a side, away from the substrate, of the light-emitting device comprises: forming the plurality of optical sensors on the non-light-emitting region on the side, away from the substrate, of the light-emitting device under the condition that a temperature is lower than a target temperature, the target temperature being the highest tolerable temperature of the light-emitting device.

Optionally, the target temperature is 100° C.

Optionally, said forming a plurality of light-shielding patterns in one-to-one correspondence with the plurality of optical sensors on the substrate on which the plurality of optical sensors are formed comprises: forming a light-shielding layer on the substrate on which the plurality of optical sensors are formed; and forming an opening in the light-shielding layer to form the light-shielding pattern.

Optionally, said forming a plurality of optical sensors on a non-light-emitting region on a side, away from the substrate, of the light-emitting device comprises: forming the optical sensors on the non-light-emitting region on the side, away from the substrate, of the light-emitting device by means of an evaporation process; said forming a light-shielding layer on the substrate on which the plurality of optical sensors are formed comprises: forming the light-shielding layer on the side, away from the light-emitting device, of the optical sensor by means of a deposition process; said forming an opening in the light-shielding layer to form the light-shielding pattern comprises: forming the opening in the light-shielding layer by means of a patterning process to form the light-shielding pattern.

### BRIEF DESCRIPTION OF THE DRAWINGS

FIG. 1 is a structural schematic view of a display panel provided by an embodiment of the present disclosure;

FIG. 2 is a structural schematic view of another display panel provided by an embodiment of the present disclosure;

FIG. 3 is a schematic top view of a light-emitting device provided by an embodiment of the present disclosure;

FIG. 4 is a schematic top view of another light-emitting device provided by an embodiment of the present disclosure;

FIG. 5 is a schematic view showing transmission of a fingerprint-reflected optical signals provided by an embodiment of the present disclosure;

FIG. 6 is a structural schematic view of an optical sensor provided by an embodiment of the present disclosure;

FIG. 7 is a structural schematic view of yet another display panel provided by an embodiment of the present disclosure;

FIG. 8 is a structural schematic view of yet another display panel provided by an embodiment of the present disclosure;

FIG. 9 is a structural schematic view of yet another display panel provided by an embodiment of the present disclosure;

FIG. 10 is a flow chart of a method for manufacturing a display panel according to an embodiment of the present disclosure; and

FIG. 11 is a flow chart of a process for forming optical sensing modules according to an embodiment of the present disclosure.

### DETAILED DESCRIPTION

The embodiments of the present disclosure will be described in further detail with reference to the accompanying drawings, to clearly present the principles and advantages of the present disclosure.

Currently, a method for realizing full-screen fingerprint recognition in a display region of a display panel includes: disposing optical sensors in TFTs of the display panel, and enabling orthographic projections of the optical sensors on a light-emitting device to be located within a non-light-emitting region of the light-emitting device; forming openings in the position, corresponding to the optical sensors, in a light-emitting layer of the light-emitting device, such that fingerprint-reflected optical signals could pass through the openings in the light-emitting device to reach the optical sensors; and performing follow-up processing such as fingerprint matching analysis by means of a processing component that is connected to the optical sensor, to realize fingerprint recognition. The light-emitting device contains a cathode, a light-emitting layer and an anode.

However, on one hand, when the fingerprint-reflected optical signals pass through the cathode and the anode in the light-emitting device, part of the light energy would be lost, resulting in that only relatively weaker fingerprint-reflected optical signals reach the optical sensors. On the other hand, since the light-emitting device would emit light toward all directions, light emitted by the light-emitting device toward the TFTs may directly hit the optical sensors, which would lead to the overexposure of the optical sensors and cause great interference to the optical sensors. Therefore, the current full-screen fingerprint recognition has relatively lower reliability.

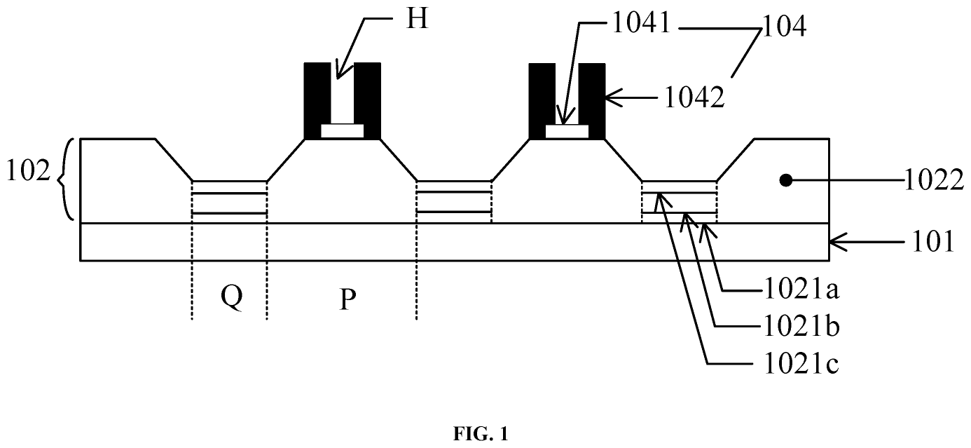

FIG. 1 is a structural schematic view of a display panel provided by an embodiment of the present disclosure. As shown in FIG. 1, the display panel may include a substrate 101, as well as a light-emitting device 102 and a plurality of optical sensing modules 104, which are sequentially located on the substrate 101 in a direction away from the substrate 101.

That is, the display panel shown in FIG. 1 includes a substrate 101, as well as a light-emitting device 102 and a plurality of optical sensing modules 104, which are located on one side of the substrate 101. The plurality of optical sensing modules 104 are located on the side, away from the substrate 101, of the light-emitting device 102. An orthographic projection of each optical sensing module 104 on the light-emitting device 102 is located within a non-light-emitting region P of the light-emitting device 102.

Optionally, see FIG. 1, each optical sensing module 104 includes an optical sensor 1041 and a light-shielding pattern 1042. An opening H is located in the light-shielding pattern 1042. The opening H is located on a side on which the light receiving face of the optical sensor 1041 is located, and an orthographic projection of the opening H on the substrate 101 and an orthographic projection of the light receiving face of the optical sensor 1041 on the substrate 101 overlap each other. The light receiving face of the optical sensor 1041 is a face away from the substrate 101.

Optionally, the orthographic projection of the opening in the light-shielding pattern on the substrate covers the orthographic projection of the light receiving face of the optical sensor on the substrate. The non-light-emitting region P of the light-emitting device is a non-pixel region on the light-emitting device. The non-pixel region on the light-emitting device is, namely, the non-pixel region on the display panel.

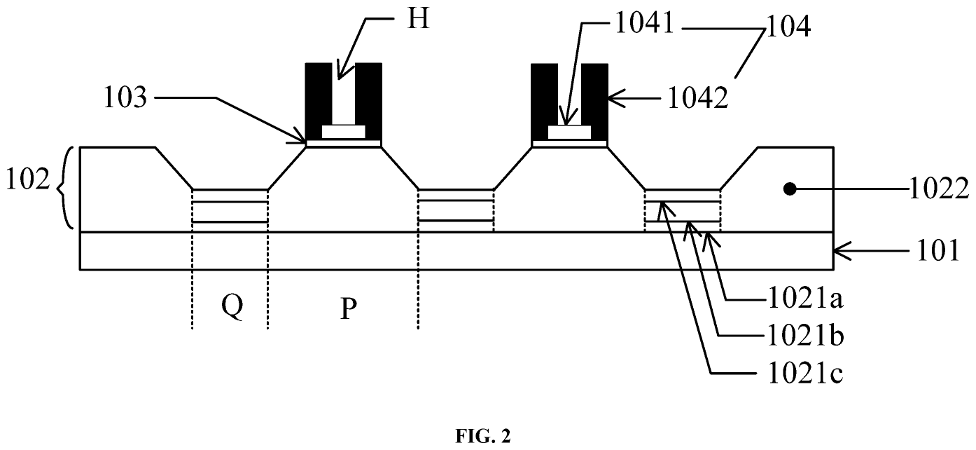

Optionally, referring to FIG. 2, the display panel further includes a conductive wire 103. The conductive wire 103 may be located between the light-emitting device 102 and the plurality of optical sensing modules 104. The conductive wire 103 is electrically connected to the optical sensor 1041.

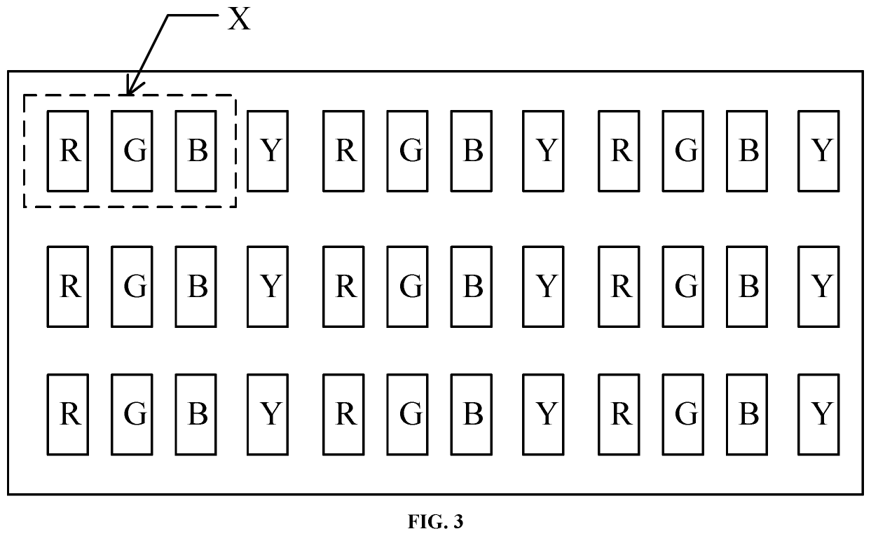

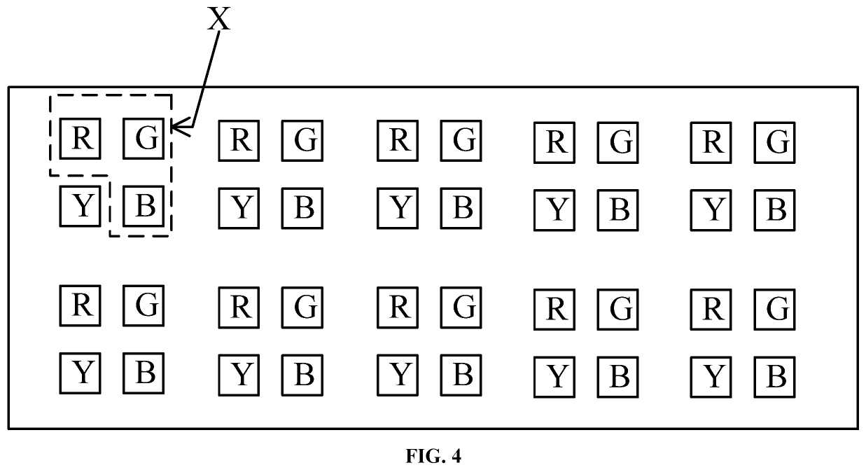

Exemplarily, FIG. 3 and FIG. 4 are respectively top views of light-emitting devices provided by the embodiments of the present disclosure. Referring to FIG. 3 or FIG. 4, the light-emitting device includes a pixel region X and a non-pixel region Y. The pixel region X may include a red pixel R, a green pixel G and a blue pixel B. When arranging the optical sensing module, the orthographic projection of the optical sensing module on the light-emitting device could be located within the non-pixel region Y of the light-emitting device.

As shown in FIG. 1 and FIG. 2, the light-emitting device 102 has a light-emitting region Q and the non-light-emitting region P.

Referring to FIG. 1 and FIG. 2, the light-emitting region Q includes a first electrode 1021a, a light-emitting layer 1021b and a second electrode 1021c which are sequentially located on the substrate 101 in a direction away from the substrate 101. The first electrode is one of an anode and a cathode, and the second electrode is the other. That is, the first electrode is a cathode and the second electrode is an anode. Or, the first electrode is an anode and the second electrode is a cathode. The light-emitting layer includes a first carrier injection layer, a first carrier transport layer, an emission layer, a second carrier transport layer and a second carrier injection layer. A first carrier is one of a hole and an electron, and a second carrier is the other.

Exemplarily, the light-emitting region includes an anode, a hole injection layer, a hole transport layer, an emission layer, an electron transport layer, an electron injection layer and a cathode which are sequentially located in the direction away from the substrate. Or, the light-emitting region includes a cathode, an electron injection layer, an electron transport layer, an emission layer, a hole transport layer, a hole injection layer and an anode which are sequentially located in the direction away from the substrate.

Referring to FIG. 1 and FIG. 2, the non-light-emitting region P includes a pixel define layer 1022 located on the substrate 101.

Optionally, in an embodiment of the present disclosure, the light-emitting device may be a self-luminous device, such as an OLED device, or a Quantum Dot Light Emitting Diodes (QLED) device.

In summary, in the display panels provided by the embodiments of the present disclosure, since the optical sensing modules are located on the side, away from the substrate, of the light-emitting device, fingerprint-reflected optical signals could directly reach a light receiving face of an optical sensor after passing through an opening in the light-shielding pattern. In comparison with the related art, the fingerprint-reflected optical signals do not need to pass through the light-emitting device, so that the strength of the fingerprint-reflected optical signals that reach an optical sensor is increased. In addition, since the light receiving face of an optical sensor is the face away from the substrate, light emitted by the light-emitting device would not directly hit the light receiving face to cause interference to the optical sensor. Thus, the reliability of fingerprint recognition of the display panel is improved.

Compared with a display panel in the related art, in the display panel provided by the embodiments of the present disclosure, the strength of the fingerprint-reflected optical signals that reach the optical sensors is improved. As such, the required brightness of the display panel upon conducting fingerprint recognition would be lowered. Also, the battery performance of the display panel would be improved correspondingly while the reliability of fingerprint recognition is guaranteed.

Since the fingerprint-reflected optical signals reach the light receiving faces of the optical sensors through the openings in the light-shielding pattern, the size of the available light receiving faces on the optical sensors could be changed by adjusting the caliber of the openings in the light-shielding patterns. As such, the size of the available light receiving faces of the optical sensors could be conveniently adjusted according to different requirements, while unnecessary to change the structure of the optical sensors.

It should be noted that a fingerprint is an invariant feature that is inherent in a human body, unique and distinguishable from others. The fingerprint consists of a series of fingerprint ridges and fingerprint valleys on the surface of fingertip skin. Composition details of these fingerprint ridges and fingerprint valleys usually include such details as bifurcation of the fingerprint ridges, ends of the fingerprint ridges, arches, tented arches, levorotation, dextrorotation, helix or birotation. These details determine the uniqueness of a fingerprint pattern. Since the fingerprint ridges and the fingerprint valleys have different refractive indexes, when a pixel emits light, light reflected by the fingerprint ridges and light reflected by the fingerprint valleys have different strengths. Further, an optical signal reflected by the fingerprint ridges and an optical signal reflected by the fingerprint valleys are different. At last, the optical sensor generates different electrical signals. To guarantee the accuracy of fingerprint recognition and to prevent the electrical signals generated by the adjacent optical sensors from interference, the caliber of the openings in the light-shielding patterns could be adjusted to enable each optical sensor to receive the fingerprint-reflected optical signals within a certain angle range. Thus, fingerprint regions corresponding to the fingerprint-reflected optical signals that are received by the adjacent optical sensors have no overlap or a small overlap.

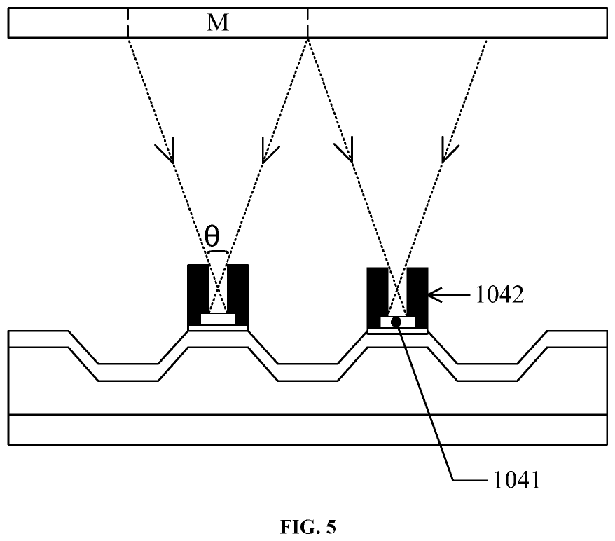

Exemplarily, FIG. 5 is a schematic view showing transmission of fingerprint-reflected optical signals provided by an embodiment of the present disclosure. As shown in FIG. 5, each optical sensor 1041 receives the optical signals reflected by a target fingerprint region M (the target fingerprint region M is a region on a touch screen of a display device) of a fingerprint through the opening in the light-shielding pattern 1042. The angle of the fingerprint-reflected optical signals received by each optical sensor 1041 is θ. The target fingerprint regions M corresponding to two adjacent optical sensors do not overlap each other.

Optionally, the angle of the fingerprint-reflected optical signals received by the optical sensors could be changed by adjusting the caliber of the openings in the light-shielding patterns and the thickness of the light-shielding patterns. The smaller the caliber of the openings is and the thicker the light-shielding patterns is, the smaller the angle of the fingerprint-reflected optical signals received by each optical sensor is, the smaller the corresponding fingerprint regions are, the less the interference between the adjacent optical sensors is, and the higher definition the fingerprint image as finally acquired has.

Optionally, the caliber of the openings in the light-shielding patterns is in positive correlation with the thickness of the light-shielding patterns. The openings may be circular openings, rectangular openings or openings in other shapes. Exemplarily, when the opening is a circular opening, the caliber of the opening refers to the diameter of the opening. When the opening is a rectangular opening, the caliber of the opening refers to the diagonal length of the rectangle.

Optionally, when the openings are circular openings, the ratio of the thickness of the light-shielding patterns to the diameter of the openings may be greater than 8. When the ratio of the thickness of the light-shielding patterns to the diameter of the openings in FIG. 5 is greater than 8, the angle θ of the fingerprint-reflected optical signals received by each optical sensor is smaller than 16°.

It should be noted that, considering the distribution density of the optical sensors in the display device and the distance between the optical sensors and fingerprint recognition regions of a display screen, when the angle of the fingerprint-reflected optical signals received by the optical sensors is smaller than 16°, the target fingerprint regions M corresponding to the two adjacent optical sensors have nearly no overlap. Thus, the interference between the adjacent optical sensors could be reduced. Further, the definition of the finally acquired fingerprint image could be improved.

Optionally, an orthographic projection of the conductive wire on the light-emitting device is located within the non-light-emitting region of the light-emitting device, such that the conductive wire would not adversely influence the display effect of the display panel.

Optionally, the display panel may further include a processing component. Each optical sensor may be connected to the processing component in the display panel through the conductive wire. That is, the conductive wire could be used to connect the optical sensor and the processing component. The processing component is configured to recognize the fingerprint pattern in accordance with electrical signals transmitted by the optical sensors. The electrical signals are generated after the optical sensors receive the fingerprint-reflected optical signals. The processing component may be a processing chip or a processor. Since an optical signal reflected by the fingerprint ridges is different from that reflected by the fingerprint valleys, the resultant electrical signals generated by the optical sensors are also different. The processing component may determine locations of the fingerprint ridges and the fingerprint valleys in accordance with the electrical signals transmitted by each optical sensor to determine the fingerprint pattern, and then compares it with a fingerprint pattern pre-stored in a fingerprint database. If the two fingerprint patterns are the same, it indicates a successful fingerprint authentication. If the two fingerprint patterns are not the same, it indicates a failed fingerprint authentication.

Optionally, the conductive wire may be a metal wire, and for example, may be made from molybdenum.

In an embodiment of the present disclosure, the optical sensors may be photodiode (PIN) optical sensors, Photo TFT optical sensors (e.g., an Indium Gallium Zinc Oxide (IGZO) TFT optical sensors) or the like. The types of the optical sensors are not limited in the embodiments of the present disclosure.

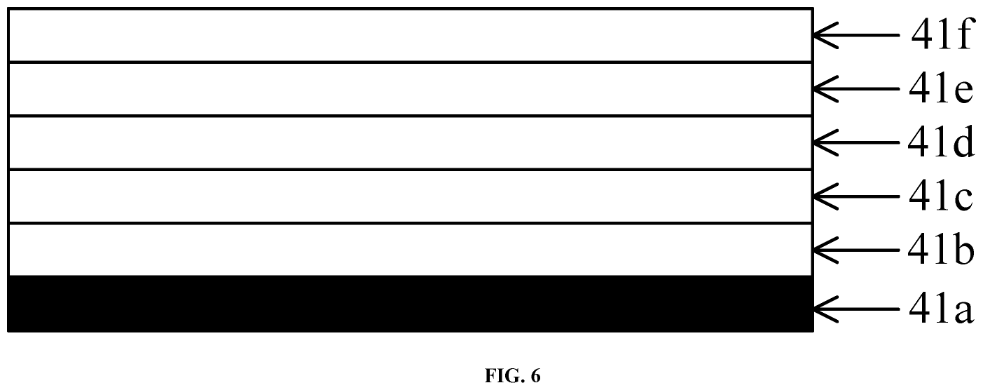

Exemplarily, FIG. 6 is a structural schematic view of an optical sensor provided by an embodiment of the present disclosure. As shown in FIG. 6, the optical sensor may include a first electrode 41a, a first carrier injection layer 41b, a current generation layer 41c, a second carrier injection layer 41d and a second electrode 41e which are sequentially located in the direction away from the light-emitting device. The first electrode is a non-transparent electrode and the second electrode is a transparent electrode. When the first electrode is a cathode and the second electrode is an anode, the first carrier injection layer is an electron injection layer and the second carrier injection layer is a hole injection layer. When the first electrode is an anode and the second electrode is a cathode, the first carrier injection layer is a hole injection layer and the second carrier injection layer is an electron injection layer.

Optionally, the first electrode is a non-transparent metal electrode and the second electrode is a transparent electrode, e.g., an Indium Tin Oxide (ITO) electrode. The first electrode, close to the light-emitting device, in the optical sensor is a non-transparent electrode, which could shield the light emitted by the light-emitting device toward the optical sensors and prevent the light emitted by the light-emitting device from causing interference to the optical sensors. Or, the first electrode is a transparent electrode. Then, a light-shielding layer may be formed on the side, close to the light-emitting device, of the optical sensors to shield light emitted by the light-emitting device toward the optical sensors. Thus, the light emitted by the light-emitting device is prevented from causing interference to the optical sensors.

Optionally, as shown in FIG. 6, the optical sensor may further include a film encapsulation layer 41f located on the side, away from the first electrode 41a, of the second electrode 41e. The film encapsulation layer may protect the internal structure of the optical sensor and prevent the internal structure from being corroded by water and oxygen. The film encapsulation layer is a transparent film layer.

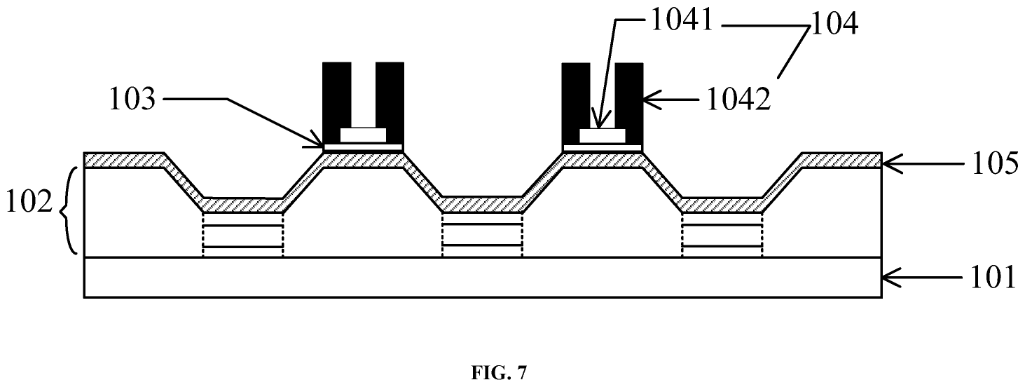

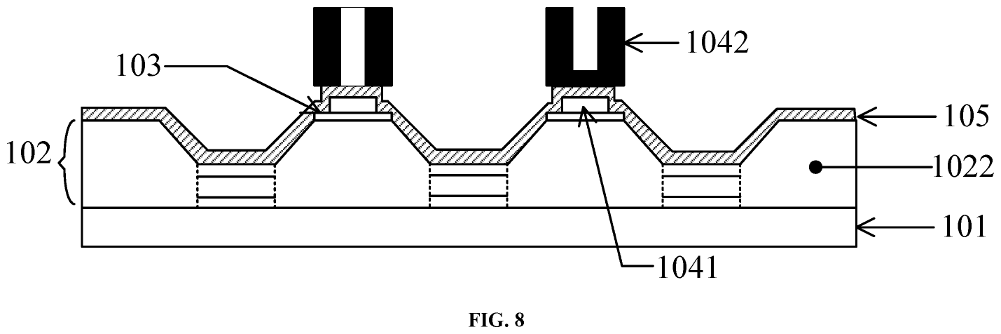

Optionally, FIG. 7 and FIG. 8 are respectively structural schematic views of display panels provided by the embodiments of the present disclosure. As shown in FIG. 7 and FIG. 8, the display panels further include an insulating film encapsulation layer 105 located on the side, away from the substrate 101, of the light-emitting device 102.

Referring to FIG. 7, the optical sensing module 104 is located on the side, away from the substrate 101, of the insulating film encapsulation layer 105. The insulating film encapsulation layer is configured to encapsulate the light-emitting device to prevent the light-emitting device from failing to work once water and oxygen enter the light-emitting device.

Referring to FIG. 8, the optical sensor 1041 is located between the light-emitting device 102 and the insulating film encapsulation layer 105. Since the orthographic projection of the optical sensor 1041 on the light-emitting device 102 is located within the non-display region of the light-emitting device 102, it could be determined that the optical sensor 1041 is located between a pixel define layer 1022 and the insulating film encapsulation layer 105. The light-shielding pattern 1042 is located on the side, away from the substrate 101, of the insulating film encapsulation layer 105. That is, after the light-emitting device is formed on the substrate, the conductive wire and the optical sensors are formed on the pixel define layer of the light-emitting device. Then, film encapsulation is performed on the display panel. The insulating film encapsulation layer may be used to encapsulate the light-emitting device and the optical sensors simultaneously. There is no need to separately encapsulate the light-emitting device and the optical sensors, so that the preparation process is simplified.

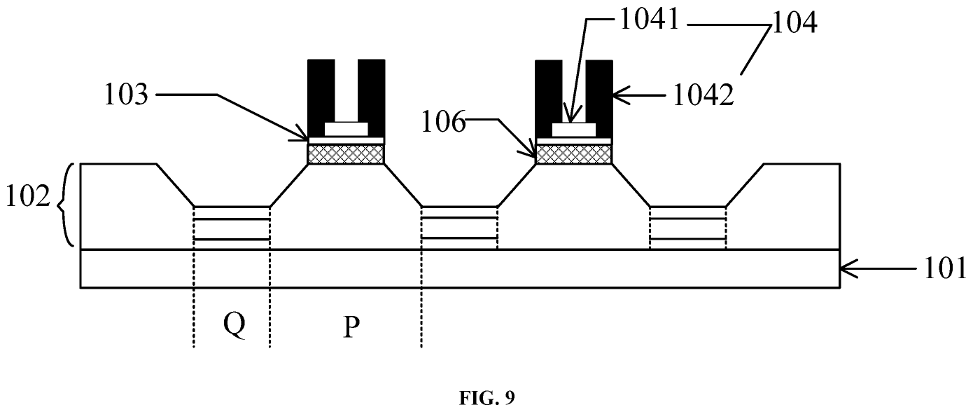

FIG. 9 is a structural schematic view of yet another display panel provided by an embodiment of the present disclosure. As shown in FIG. 9, the display panel may further include TFTs 106 located on the side, away from the substrate 101, of the light-emitting device 102. Optionally, referring to FIG. 9, the TFTs may be located within the non-light-emitting region P in the display region of the display panel, or may be located on a non-display region (namely, a border position of the display panel) of the display panel. The TFTs are electrically connected to the optical sensors. A light-shielding material is located on the side, close to the substrate, of the channel region (the channel region is a region that may form a channel on the TFT when the TFT is turned on) of a TFT. The TFTs are configured to control the exposure time of the optical sensors. When the TFTs serve as a switch of the optical sensors, the exposure time of the optical sensors could be conveniently controlled. By appropriately prolonging the exposure time of the optical sensors, the number of photons in the fingerprint-reflected optical signals received by the optical sensors could be increased, the definition of the finally acquired fingerprint image could be improved, and the accuracy of fingerprint recognition could also be improved. In addition, by arranging the light-shielding material on the side, close to the substrate, of the channel region of the TFTs, light emitted by the light-emitting device could be prevented from directly hitting the channel region of the TFTs. Thus, characteristic drift of the TFTs is avoided.

Optionally, the plurality of optical sensing modules may be in periodic arrangement. The light-emitting device may include a plurality of pixel units in periodic arrangement. The plurality of optical sensing modules and the plurality of pixel units are located in one-to-one correspondence. That is, each optical sensing module corresponds to one pixel unit, and the periodic arrangement pattern of the plurality of optical sensing modules is the same as that of the plurality of pixel units. For example, referring to FIG. 3 or FIG. 4, each pixel unit includes a red pixel R, a green pixel G and a blue pixel B. An optical sensing module is located within the non-pixel region Y adjacent to each pixel unit. The optical sensing modules are arranged on the basis of the periodic arrangement pattern of the plurality of pixel units, which makes the distribution density of the optical sensing modules relatively higher while the distribution uniformity of the optical sensing modules in the display panel is guaranteed. Further, the accuracy of fingerprint recognition in each position of the display region could be guaranteed.

Optionally, the light-shielding patterns may be made from a black matrix material. The black matrix material has already been extensively applied to light-shielding structure in the display device, and its preparation process is relatively mature. In the technological process of using the black matrix material to form light-shielding pattern, the temperature is relatively lower, so that the light-emitting device could be protected against damage. The black matrix material may be a non-photosensitive polyimide material doped with black low-valence-state titanium oxide (e.g., Titanium Black particle). The light-shielding patterns may also be made from other light-shielding materials. The light-shielding materials are not limited in the embodiments of the present disclosure.

In summary, in the display panels provided by the embodiments of the present disclosure, since the optical sensing modules are located on the side, away from the substrate, of the light-emitting device, fingerprint-reflected optical signals could directly reach the light receiving face of an optical sensor after passing through an opening in the light-shielding pattern. In comparison with the related art, the fingerprint-reflected optical signals do not need to pass through the light-emitting device, so that the strength of the fingerprint-reflected optical signals that reach the optical sensors is increased. In addition, since the light receiving face of an optical sensor is the face away from the substrate, light emitted by the light-emitting device would not directly hit the light receiving face to cause interference to the optical sensor. Thus, the reliability of fingerprint recognition of the display panel is improved.

The embodiments of the present disclosure provide a display device including a display panel. The display panel comprises a substrate, a light-emitting device and a plurality of optical sensing modules, the light-emitting device and the plurality of optical sensing modules are located on one side of the substrate. The plurality of optical sensing modules are located on a side, away from the substrate, of the light-emitting device.

An orthographic projection of each optical sensing module on the light-emitting device is located within a non-light-emitting region of the light-emitting device.

Optionally, each optical sensing module comprises an optical sensor and a light-shielding pattern; an opening

is located in the light-shielding pattern. The opening is located on a side on which the light receiving face of the optical sensor is located; and an orthographic projection of the opening on the substrate and an orthographic projection of the light receiving face of the optical sensor on the substrate overlap each other.

Optionally, the display panel may be a display panel shown in any of FIGS. 1, 2 and FIGS. 7-9.

Optionally, the display devices may further include a transparent cover plate located on the side where a light-emitting face of the display panel is located. Generally, a circular polaroid is located on the current transparent cover plate to prevent the internal structure of the display device from being seen under strong light from the side where a display face of the display device is located, which would adversely affect the appearance of the display device. The transparent cover plate may be a glass cover plate.

Optionally, the display device may be any product or component with a display function, such as a mobile phone, a tablet PC, a television, a display, a laptop, a digital photo frame and a navigator.

In summary, in the display devices provided by the embodiments of the present disclosure, since the optical sensing modules are located on the side, away from the substrate, of the light-emitting device, fingerprint-reflected optical signals could directly reach a light receiving face of an optical sensor after passing through an opening in a light-shielding pattern. In comparison with the related art, the fingerprint-reflected optical signals do not need to pass through the light-emitting device, so that the strength of the fingerprint-reflected optical signals that reach ab optical sensor is increased. In addition, since the light receiving face of an optical sensor is the face away from the substrate, light emitted by the light-emitting device would not directly hit the light receiving face to cause interference to the optical sensor. Thus, the reliability of fingerprint recognition of the display panel is improved.

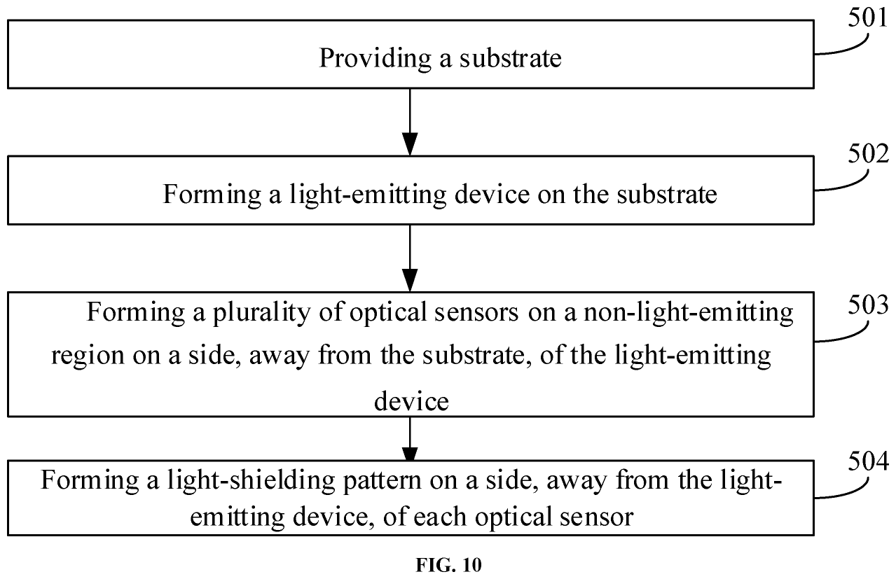

FIG. 10 is a flow chart of a method for manufacturing a display panel according to an embodiment of the present disclosure. As shown in FIG. 10, the method includes the following steps: step 501, providing a substrate; step 502, forming a light-emitting device on the substrate; step 503, forming a plurality of optical sensing modules on a non-light-emitting region on the side, away from the substrate, of the light-emitting device.

Optionally, step 503 includes the following processes: step 5031, forming a plurality of optical sensors on the non-light-emitting region on the side, away from the substrate, of the light-emitting device; and step 5032, forming a plurality of light-shielding patterns in one-to-one correspondence with the plurality of optical sensors on the substrate on which the plurality of optical sensors are formed.

An opening is formed in a light-shielding pattern, and the opening is located on a side on which the light receiving face of the optical sensor is located, and an orthographic projection of the opening on the substrate and an orthographic projection of a light receiving face of the optical sensor on the substrate overlap each other. An orthographic projection of the light-shielding pattern on the light-emitting device is located within a non-light-emitting region of the light-emitting device.

An optical sensor and a light-shielding pattern constitute an optical sensing module. Optionally, referring to FIG. 1 for the structure of the display panel.

In summary, in the methods for manufacturing the display panel provided by the embodiments of the present disclosure, since the optical sensing modules are located on the side, away from the substrate, of the light-emitting device, fingerprint-reflected optical signals could directly reach the light receiving face of an optical sensor after passing through an opening in the light-shielding pattern. In comparison with the related art, the fingerprint-reflected optical signals do not need to pass through the light-emitting device, so that the strength of the fingerprint-reflected optical signals that reach the optical sensor is increased. In addition, since the light receiving face of an optical sensor is the face away from the substrate, light emitted by the light-emitting device would not directly hit the light receiving face to cause interference to the optical sensor. Thus, the reliability of fingerprint recognition of the display panel is improved.

Optionally, after the light-emitting device is formed on the substrate, the process of the above method may further include: forming a conductive wire on the substrate on which the light-emitting device is formed. Correspondingly, the process of step 5031 includes: forming the optical sensors on the substrate on which the conductive wire is formed, and electrically connecting the conductive wire with the optical sensors. Referring to FIG. 2 for the structure of the obtained display panel.

Optionally, said forming a conductive wire on the substrate on which the light-emitting device is formed may include: forming the conductive wire on the non-light-emitting region on the side, away from the substrate, of the light-emitting device by means of sputtering under the condition that a temperature is lower than a target temperature. The target temperature is the highest tolerable temperature of the light-emitting device.

Optionally, the conductive wire may be a metal wire. For example, the metal wire may be made from molybdenum or titanium-aluminium-titanium alloy. Since the metal wire has good electroconductivity, the electrical signals generated by the optical sensors could be effectively transmitted to a processing component. Thus, the reliability of fingerprint recognition is improved. The metal wire may be made by means of a low-temperature process, such that the light-emitting device is prevented from damage. The conductive wire made of metal is relatively better in flexibility, low in probability of fracture and relatively higher in reliability.

Optionally, the target temperature may be 100° C. Exemplarily, the conductive wire may be formed by sputtering a target material to be coated on a pixel define layer of the light-emitting device at 80° C. , wherein the target material may be molybdenum. Thus, the light-emitting device is protected against damage during the forming of the conductive wire.

Optionally, said forming the plurality of optical sensors on the non-light-emitting region on the side, away from the substrate, of the light-emitting device may include: forming the plurality of optical sensors on the non-light-emitting region on the side, away from the substrate, of the light-emitting device under the condition that a temperature is lower than a target temperature.

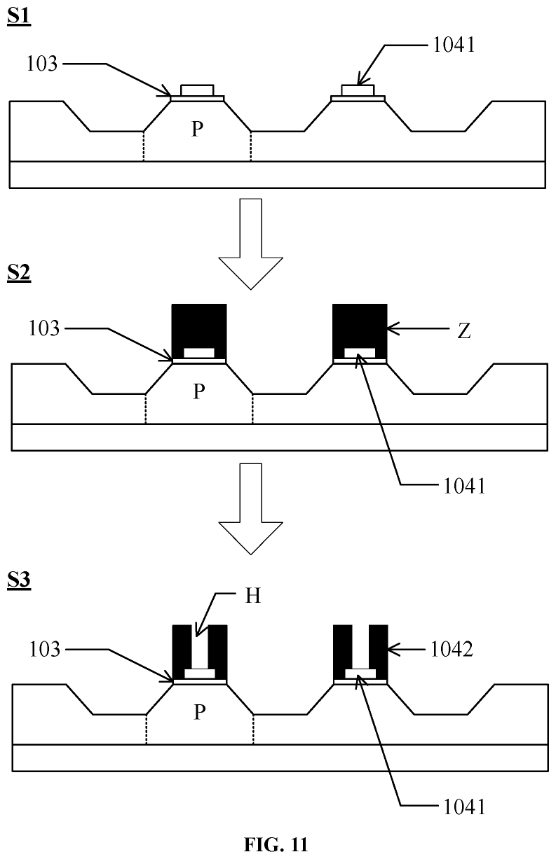

Exemplarily, FIG. 11 is a flow chart of a process for forming a plurality of optical sensing modules on a substrate on which a conductive wire is formed according to an embodiment of the present disclosure. As shown in FIG. 11, the process includes the following steps. In S1, an optical sensor 1041 is formed on a non-light-emitting region P on which a conductive wire 103 is formed.

Optionally, the optical sensors are formed on the non-light-emitting region of the conductive wire by means of an evaporation process. Alternatively, the optical sensors are formed on the non-light-emitting region on the side, away from the substrate, of the light-emitting device by means of an evaporation process.

Exemplarily, FIG. 6 is a structural schematic view of an optical sensor provided by an embodiment of the present disclosure. As shown in FIG. 6, the optical sensor may include a first electrode 41a, a first carrier injection layer 41b, a current generation layer 41c, a second carrier injection layer 41d and a second electrode 41e which are sequentially located in the direction away from the light-emitting device. The first electrode is a non-transparent electrode and the second electrode is a transparent electrode. When the first electrode is a cathode and the second electrode is an anode, the first carrier injection layer is an electron injection layer and the second carrier injection layer is a hole injection layer. When the first electrode is an anode, and the second electrode is a cathode, the first carrier injection layer is a hole injection layer and the second carrier injection layer is an electron injection layer.

It should be noted that, when the first electrode, close to the light-emitting device, in an optical sensor is a non-transparent electrode, the light emitted by the light-emitting device toward the optical sensor could be shielded, which helps prevent the light emitted by the light-emitting device from causing interference to the optical sensor.

Optionally, the evaporation process may be adopted to sequentially form the first electrode, the first carrier injection layer, the current generation layer, the second carrier injection layer and the second electrode on the non-light-emitting region on which the conductive wire is formed. Since the electron injection layer, the current generation layer and the hole injection layer are transparent structural layers and have less influence on the light emission of the light-emitting device, they could be located as whole layers to simplify the preparation process. That is, orthographic projections of the electron injection layer, the current generation layer and the hole injection layer on the light-emitting device could completely overlap a region where the light-emitting device is located, which are not limited in the embodiments of the present disclosure.

Optionally, a film encapsulation layer may be further formed on the second electrode by means of an evaporation process.

It should be noted that during the evaporation for forming the optical sensors, the surface temperature of the light-emitting device is lower than 100° C. As such, the light-emitting device is protected against damage.

The process shown in FIG. 11 further includes: step S2, forming light-shielding layers Z on the substrate on which the plurality of optical sensors 1041 are formed.

Optionally, the light-shielding layers are formed on the side, away from the light-emitting device, of the optical sensors by means of a deposition process. For example, low-temperature (e.g., lower than 100° C.) Plasma Enhanced Chemical Vapor Deposition (PECVD) may be adopted to form the light-shielding layers on the optical sensors.

The process shown in FIG. 11 further includes: S3, forming openings H in the light-shielding layers Z to form light-shielding patterns 1042.

Optionally, the openings may be formed in the light-shielding layers by means of a patterning process to form the light-shielding patterns. The patterning process includes photoresist coating, exposure, developing, etching and photoresist stripping. In the embodiments of the present disclosure, the openings may be formed in the light-shielding layers only by means of one-time patterning process. Thus, only one mask is required. The cost is relatively lower and the process is simple.

It should be noted that, the sequence of steps in the methods for manufacturing the display panel, provided by the embodiments of the present disclosure, may be appropriately adjusted, and the steps may be removed or new steps may be added depending on specific situation. Any method that is easily conceivable for those skilled in the art within the scope of the technology disclosed by the present disclosure is intended to be included in the scope of protection of the present disclosure, and therefore is not further described herein.

In summary, in the methods for manufacturing the display panel, provided by the embodiments of the present disclosure, since the optical sensing modules are located on the side, away from the substrate, of the light-emitting device, fingerprint-reflected optical signals could directly reach the light receiving face of an optical sensor after passing through an opening in the light-shielding pattern. In comparison with the related art, the fingerprint-reflected optical signals do not need to pass through the light-emitting device, so that the strength of the fingerprint-reflected optical signals that reach an optical sensor is increased. In addition, since the light receiving face of an optical sensor is the face away from the substrate, light emitted by the light-emitting device would not directly hit the light receiving face to cause interference to the optical sensor. Thus, the reliability of the fingerprint recognition of the display panel is improved.

All structures of the display panel involved in the method of the above embodiments have already been described in detail in the embodiments relating to the devices, and therefore, are not illustrated in detail herein.

The foregoing descriptions are only optional embodiments of the present disclosure, and are not intended to limit the present disclosure. Within the spirit and principles of the disclosure, any modifications, equivalent substitutions, improvements, etc., are within the protection scope of the appended claims of the present disclosure.

What is claimed is:

1. A display panel, comprising:
a substrate, a light-emitting device and a plurality of optical sensing module modules, the light-emitting device and the plurality of optical sensing modules are located on one side of the substrate, the plurality of optical sensing modules are located on a side, away from the substrate, of the light-emitting device;
wherein an orthographic projection of each optical sensing module on the light-emitting device is located within a non-light-emitting region of the light-emitting device.

2. The display panel according to claim 1, wherein
each optical sensing module comprises an optical sensor and a light-shielding pattern; an opening is located in the light-shielding pattern; the opening is located on a side on which the light receiving face of the optical sensor is located; and an orthographic projection of the opening on the substrate and an orthographic projection of the light receiving face of the optical sensor on the substrate overlap each other.

3. The display panel according to claim 1, wherein
a caliber of the opening is in positive correlation with a thickness of the light-shielding pattern.

4. The display panel according to claim 2, wherein the opening is a circular opening; and
the ratio of the thickness of the light-shielding pattern to the caliber of the opening is greater than 8.

5. The display panel according to claim 1, wherein the conductive wire is located between the light-emitting device and the plurality of optical sensing modules, and an orthographic projection of the conductive wire on the light-emitting device is located within the non-light-emitting region.

6. The display panel according to claim 2, wherein the optical sensor comprises a first electrode, a first carrier injection layer, a current generation layer, a second carrier injection layer and a second electrode which are sequentially located in a direction away from the light-emitting device; and
wherein the first electrode is a non-transparent electrode, and the second electrode is a transparent electrode.

7. The display panel according to claim 2, further comprising a thin film transistor electrically connected to the optical sensor, wherein a light-shielding material is located on a side, close to the substrate, of a channel region of the thin film transistor; and
the thin film transistor is configured to control exposure time of the optical sensor.

8. The display panel according to claim 1, wherein the light-emitting device comprises a plurality of pixel units in periodic arrangement; and
the plurality of optical sensing modules and the plurality of pixel units are in one-to-one correspondence.

9. (canceled).

10. The display panel according to claim 2, wherein a light-emitting region of the light-emitting device comprises a first electrode, a light-emitting layer and a second electrode which are sequentially located on the substrate in a direction away from the substrate; and
the first electrode is one of an anode and a cathode, and the second electrode is the other.

11. The display panel according to claim 2, further comprising an insulating film encapsulation layer located on a side, away from the substrate, of the light-emitting device.

12. The display panel according to claim 11, wherein
the optical sensing module is located on a side, away from the substrate, of the insulating film encapsulation layer.

13. A display device, comprising a display panel, wherein the display panel comprises a substrate, a light-emitting device and a plurality of optical sensing modules, the light-emitting device and the plurality of optical sensing modules are located on one side of the substrate, and the plurality of optical sensing modules are located on a side, away from the substrate, of the light-emitting device;
wherein an orthographic projection of each optical sensing module on the light-emitting device is located within a non-light-emitting region of the light-emitting device.

14. A method for manufacturing a display panel, comprising:
providing a substrate;
forming a light-emitting device on the substrate; and
forming a plurality of optical sensing modules on a non-light-emitting region on a side, away from the substrate, of the light-emitting device.

15. The method according to claim 23, wherein after said forming the light-emitting device on the substrate, the method further comprises:
forming a conductive wire on the substrate on which the light-emitting device is formed,
said forming a plurality of optical sensors on a non-light-emitting region on a side, away from the substrate, of the light-emitting device comprises:
forming the optical sensors on the substrate on which the conductive wire is formed, and the conductive wire is connected with the optical sensors.

16. The method according to claim 15, wherein said forming a conductive layer on the substrate on which the light-emitting device is formed comprises:
forming the conductive wire on the non-light-emitting region on the side, away from the substrate, of the light-emitting device by means of sputtering under the condition that a temperature is lower than a target temperature, the target temperature being the highest tolerable temperature of the light-emitting device.

17. The method according to claim 23, wherein said forming a plurality of optical sensors on a non-light-emitting region on a side, away from the substrate, of the light-emitting device comprises:
forming the plurality of optical sensors on the non-light-emitting region on the side, away from the substrate, of the light-emitting device under the condition that a temperature is lower than a target temperature, the target temperature being the highest tolerable temperature of the light-emitting device.

18. (canceled).

19. The method according to claim 23, wherein said forming a plurality of light-shielding patterns in one-to-one correspondence with the plurality of optical sensors on the substrate on which the plurality of optical sensors are formed comprises:
forming a light-shielding layer on the substrate on which the plurality of optical sensors are formed; and
forming an opening in the light-shielding layer to form the light-shielding pattern.

20. (canceled).

21. The display panel according to claim 2, further comprising a conductive wire and a processing component;
the conductive wire is configured to connect the optical sensor and the processing component;
the processing component is configured to recognize a fingerprint pattern in accordance with electrical signals transmitted by the optical sensor, and the electrical signals are generated based on optical signals received by the optical sensor.

22. The display panel according to claim 11, wherein
the optical sensor is located between the light-emitting device and the insulating film encapsulation layer, and the light-shielding pattern is located on a side, away from the substrate, of the insulating film encapsulation layer.

23. The method according to claim 14, wherein said forming a plurality of optical sensing modules on a non-light-emitting region on a side, away from the substrate, of the light-emitting device comprises:
forming a plurality of optical sensors on the non-light-emitting region on the side, away from the substrate, of the light-emitting device;
forming a plurality of light-shielding patterns in one-to-one correspondence with the plurality of optical sensors on the substrate on which the plurality of optical sensors are formed, openings are formed in the light-shielding patterns, the opening is located on a side on which the light receiving face of the optical sensor is located, and an orthographic projection of the opening on the substrate and an orthographic projection of the light receiving face of the optical sensor on the substrate overlap each other.
